(19) United States
(12) Patent Application Publication
(10) Pub. No.: US 2011/0310574 A1
(43) Pub. Date: Dec. 22, 2011

(54) Electronic control unit for vehicle

(75) Inventor: Kazuo Nomoto, Toyokawa-city (JP)

(73) Assignee: DENSO CORPORATION, Kariya-city (JP)

(21) Appl. No.: 13/134,352

(22) Filed: Jun. 6, 2011

(30) Foreign Application Priority Data
Jun. 17, 2010 (JP) 2010-138130

(51) Int. Cl. H05K 5/00

(52) U.S. Cl. 361/752

(57) ABSTRACT

An electronic control unit includes: a box-shaped case having an opening face; a cover closing the opening face of the case; a board interposed between the case and the cover; and an electronic component mounted to the board. The board has corner portions respectively having mount holes passing through the board. A first side and a second side defining the corner portion therebetween are located on an outer periphery of the mount hole. The board has a slit extending on an imaginary line defined to extend from the first side to the second side.

### CROSS REFERENCE TO RELATED APPLICATION

This application is based on Japanese Patent Application No. 2010-138130 filed on Jun. 17, 2010, the disclosure of which is incorporated herein by reference in its entirety.

### BACKGROUND OF THE INVENTION

1. Field of the Invention

The present invention relates to an electronic control unit mounted in a vehicle.

2. Description of Related Art

JP-A-5-206686 describes a device for protecting a print board having an event data recorder (EDR) for a vehicle. The EDR records time series vehicle information such as vehicle velocity. The vehicle information is required to be alive even after an air bag is inflated when the vehicle has a collision, for example. The print board is fixed to a frame-shaped holding jig using a guide pin. A through hole is defined at a periphery of the print board, and the guide pin passes through the through hole. An end of the print board is directly supported by the holding jig, and the other end of the print board is supported by the holding jig through an extendible connector.

That is, the print board is fixed and supported by the extendible connector and the guide pin passing through the through hole. Therefore, if a mechanical impact is applied to the print board, the impact is absorbed by the extendible connector, so that the print board is restricted from being damaged. Thus, the EDR mounted on the print board can be protected from the impact.

However, the guide pin and the extendible connector increase the number of producing processes and the material cost.

### SUMMARY OF THE INVENTION

In view of the foregoing and other problems, it is an object of the present invention to provide an electronic control unit for a vehicle.

According to an example of the present invention, an electronic control unit for a vehicle includes a box-shaped case having an opening face; a cover closing the opening face of the case; a board interposed between the case and the cover; and an electronic component mounted to the board. The board has a plurality of corner portions constructed by a first side and a second side. The corner portions respectively have mount holes passing through the board. The first side and the second side are located on an outer periphery of the mount hole. The case, the cover and the board are integrally fixed with each other by a fixing member passing through the mount hole. The board has a slit extending on an imaginary line defined to extend from the first side to the second side.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic perspective view illustrating an electronic control unit according to a first embodiment;

FIG. 2 is an exploded view illustrating the electronic control unit;

FIG. 3 is a block view illustrating circuit components mounted to a circuit board of the electronic control unit;

FIG. 4 is a schematic cross-sectional view illustrating the electronic control unit fixed to a vehicle;

FIG. 5 is a plan view illustrating the circuit board;

FIG. 6 is a plan view illustrating a modification of the circuit board;

FIG. 7 is a plan view illustrating a modification of the circuit board;

FIG. 8 is a plan view illustrating a modification of the circuit board;

FIG. 9 is a plan view illustrating a modification of the circuit board;

FIG. 10A is a schematic cross-sectional view illustrating a through slit of the circuit board, and FIG. 10B is a schematic cross-sectional view illustrating a based slit of the circuit board;

FIG. 11A is a schematic plan view illustrating a casing of an electronic control unit according to a second embodiment, and FIG. 11B is a schematic front view illustrating the casing; and

FIG. 12 is a schematic front view illustrating a casing of a comparison example.

### DETAILED DESCRIPTION OF PREFERRED EMBODIMENT

### First Embodiment

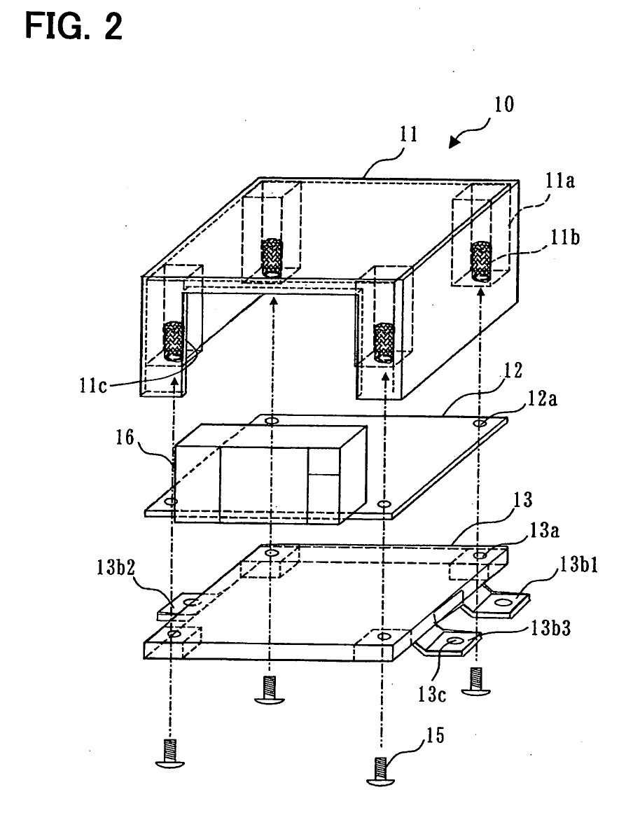

As shown in FIG. 2, an electronic control unit 10 (ECU) for a vehicle has a casing 11, a circuit board 12 and a cover 13. The casing 11 is made of resin, and has a box shape. A lower face of the casing 11 is an opening face, and the circuit board 12 is inserted into the casing 11 through the opening face. The cover 13 is fixed to close the opening face of the casing 11, and is made of a metal board.

The casing 11 has four pillar members 11a respectively fixed to four corners of the casing 11. Four concaves are respectively defined in the pillar members 11a on a lower face opposing to the circuit board 12. Four insert nuts 11b are respectively fitted into the concaves, and the cover 13 is fixed to the casing 11 by screws 15 corresponding to the nuts 11b. A box-shaped connector 16 is mounted on the circuit board 12. A rectangular aperture 11c is defined on a side face of the casing 11, and the connector 16 is fitted with the aperture 11c.

The circuit board 12 has four screw holes 12a respectively defined at four corners of the circuit board 12. The screw 15 passes through the hole 12a so that the circuit board 12 is fixed between the casing 11 and the cover 13. Positions of the screw holes 12a respectively correspond to those of the insert nuts 11b.

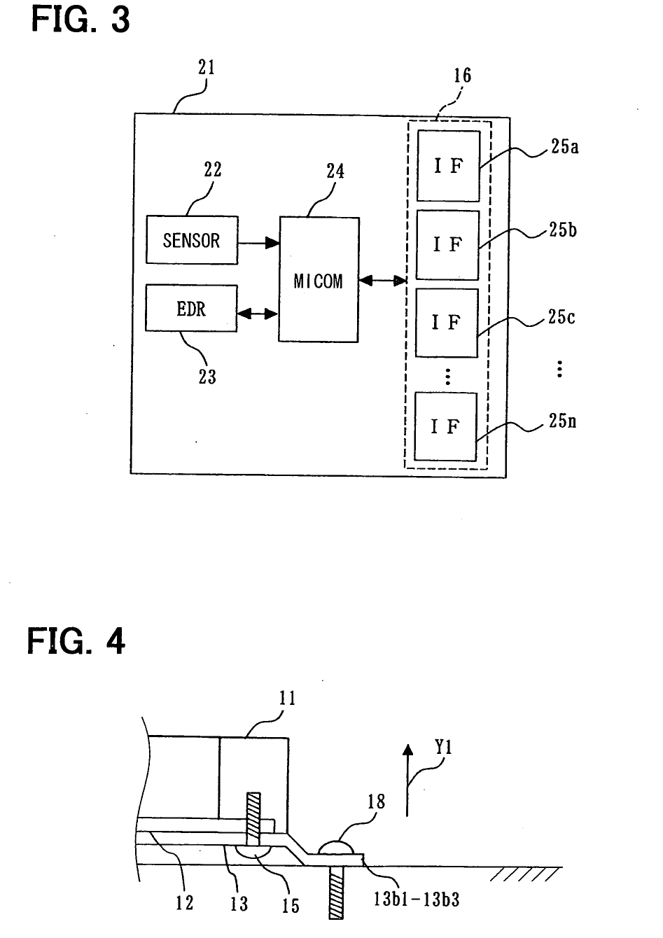

The circuit board 12 has an ECU circuit 21. As shown in FIG. 3, the ECU circuit 21 has an acceleration sensor 22, an event data recorder (EDR) device 23, a microcomputer 24 and a plurality of outside interfaces (IFs) 25a-25n. The sensor 22 detects an acceleration of the vehicle. The EDR device 23 records data of the vehicle. The microcomputer 24 is connected to each of the sensor 22, the EDR device 23 and the IFs 25a-25n. The IF 25a-25n is connected to an air bag or an outside acceleration sensor (not shown), for example. The IFs 25a-25n are connected to the connector 16.

When the microcomputer 24 determines the vehicle to have a collision based on acceleration detected by the sensor 22 or the outside sensor, the microcomputer 24 controls the air bag to be inflated, and controls the EDR device 23 to record vehicle information containing vehicle speed before-and-after the collision as time series data. As shown in FIG. 3, the EDR device 23 is connected to the microcomputer 24. Alternatively, the EDR device 23 may be included in the microcomputer 24.

As shown in FIG. 2, the cover 13 has four screw holes 13a at positions corresponding to the screw holes 12a of the circuit board 12, and the screw 15 passes through the screw hole 13a. Further, the cover 13 has two mount parts 13b1, 13b3 protruding outward from a right side of the cover 13, and has a mount part 13b2 protruding outward from a left side of the cover 13 opposite from the right side. The mount part 13b1 is defined as front-and-right mount part, the mount part 13b2 is defined as middle-and-left mount part, and the mount part 13b3 is defined as rear-and-right mount part, for example.

As shown in FIG. 4, the ECU 10 is fixed to a predetermined position of the vehicle through the mount part 13b1-13b3 by screwing a screw 18 into a hole 13c of the mount part 13b1-13b3.

The circuit board 12 is interposed between the casing 11 and the cover 13. A position of the screw hole 12a, 13a is coincident with that of the insert nut 11b. The screw 15 is inserted from a lower side of the cover 13, thereby fixing the cover 13 onto the casing 11 so as to produce the ECU 10. The ECU 10 is fixed to the vehicle by inserting the screw 18 into the hole 13c of the mount part 13b1-13b3.

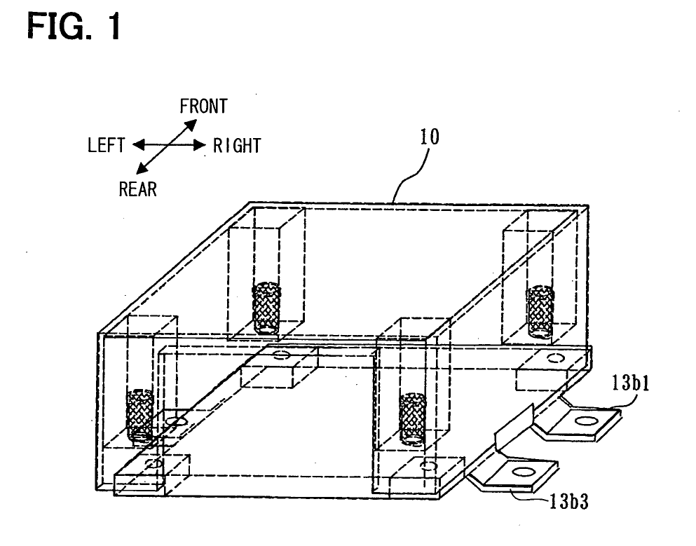

When the ECU 10 is fixed to the vehicle, as shown in FIG. 1, the connector 16 is located on a rear side of the vehicle in the ECU 10. The mount parts 13b1, 13b3 are located on a right side of the vehicle, and the mount part 13b2 is located on a left side of the vehicle. The casing 11 is located on an upper side of the vehicle.

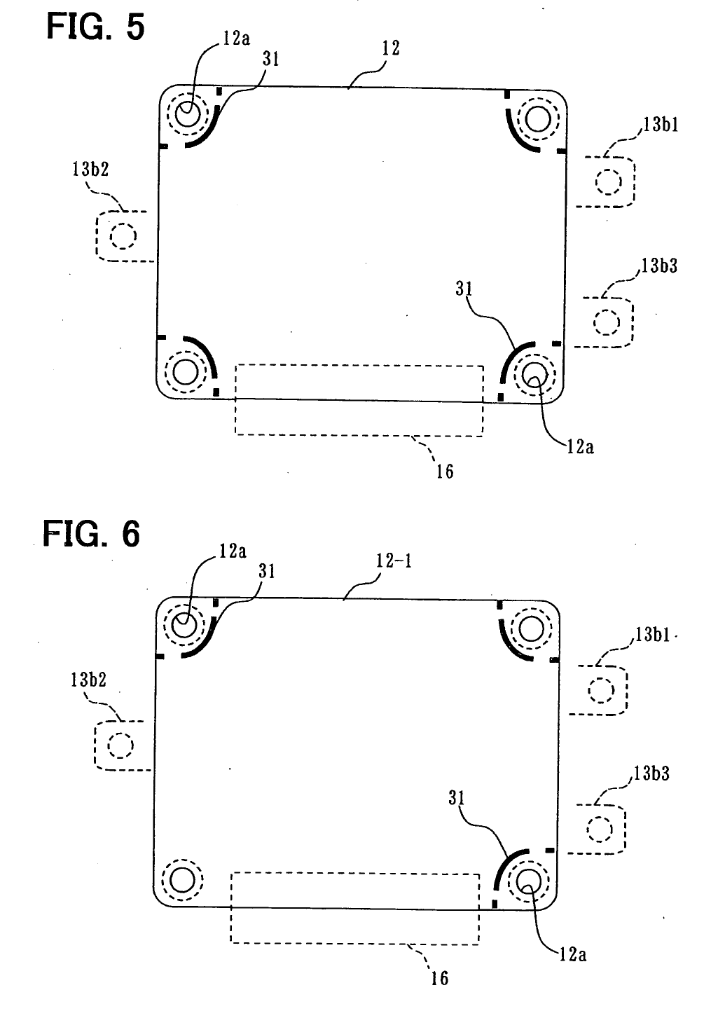

As shown in FIG. 5, a slit 31 is defined in the board 12, and is located around the screw hole 12a. The slit 31 is a groove passing through the circuit board 12 in a thickness direction. The slit 31 has a dashed shape extending along a circular shape of the screw hole 12a on an inner side of the board 12 with respect to the screw hole 12a, and a predetermined interval is defined between the slit 31 and the screw hole 12a.

That is, when a corner angle of the board 12 is defined to be constructed by a first side and a second side, the slit 31 extends from the first side to the second side in a curve shape. Further, the slit 31 is located at a position opposite from a vertex constructed by the first side and the second side through the mount hole 12a, so that the mount hole 12a is surrounded by the first side, the vertex, the second side and the slit 31.

The circuit board 12 is defined to be divided into a main area having the ECU circuit 21 and a hole area having the screw hole 12a, due to the slit 31. However, the board 12 is not completely separated into two parts, because the slit 31 has the dashed shape. The circuit board 12 is fixed to the cover 13 by the screw 15 corresponding to a fixing member.

The predetermined interval is defined between the slit 31 and the screw hole 12a in a manner that the main area of the board 12 is separated from the hole area of the board 12 through the slit 31 when the vehicle has a collision.

As shown in FIG. 4, if the vehicle having the ECU 10 has a collision, a stress is applied to the ECU 10 upward indicated by an arrow direction Y1 through the mount part 13b1, 13b2 located on the front side of the vehicle. The mount part 13b1-13b3 of the ECU 10 is pushed upward by the stress, so that the circuit board 12 is damaged and separated from the cover 13 at the slit 31. The stress is absorbed by the damaging and the separation, so that the ECU circuit 21 of the circuit board 12 can be protected.

According to the first embodiment, the board 12 is damaged at the slit 31 by the stress applied to the ECU 10 when the vehicle has a collision. Therefore, the board 12 is separated from the cover 13. The stress is absorbed by the damaging and the separation, so that the ECU circuit 21 of the board 12 can be protected. Therefore, the EDR device 23 of the ECU circuit 21 can be protected, so that the vehicle data recorded in the EDR device 23 can be read and used for analyzing the collision after the collision. This advantage can be obtained with a low cost by just defining the slit 31 on the board 12.

The circuit board 12 has the main area on which the electronic components are mounted, and the hole area in which the screw hole 12a is defined. An interface between the main area and the hole area is defined by the slit 31, but the main area and the hole area are not completely separated from each other because the slit 31 has the dashed shape. Because the main area of the board 12 is partially connected to the hole area of the board 12, the electronic components mounted to the main area of the circuit board 12 can be prevented from being affected by a resonance generated by vibration when the vehicle is running.

FIG. 6 illustrates a first modification of the first embodiment. As shown in FIG. 6, a dashed-shape slit 31 is defined at each of three corners of a circuit board 12-1 except a rear-and-left corner located on a rear-and-left side of the vehicle. In this case, because the rear-and-left corner of the board 12-1 does not have the slit 31, if the front-located mount parts 13b1, 13b2 are pushed upward in the arrow direction Y1 by the stress, the board 12-1 is damaged and separated from the cover 13 at the three corners.

The stress is absorbed by the damaging and the separation, so that the ECU circuit 21 of the board 12-1 can be protected. In FIG. 5 illustrating the first embodiment, the whole of the circuit board 12 is separated from the cover 13 because the slit 31 is respectively defined at each of the four corners. In the first embodiment, the separated board 12 may collide with the casing 11, and the electronic components mounted on the board 12 may be damaged in the collision.

In contrast, in the first modification, the slit 31 is not defined at the rear-and-left corner, as shown in FIG. 6. Therefore, the board 12-1 is fixed to the cover 13 through the rear-and-left corner even after the vehicle has the collision. Therefore, the board 12-1 can be prevented from having a collision onto a wall face of the casing 11. Thus, the electronic components mounted on the board 12-1 can be more securely protected.

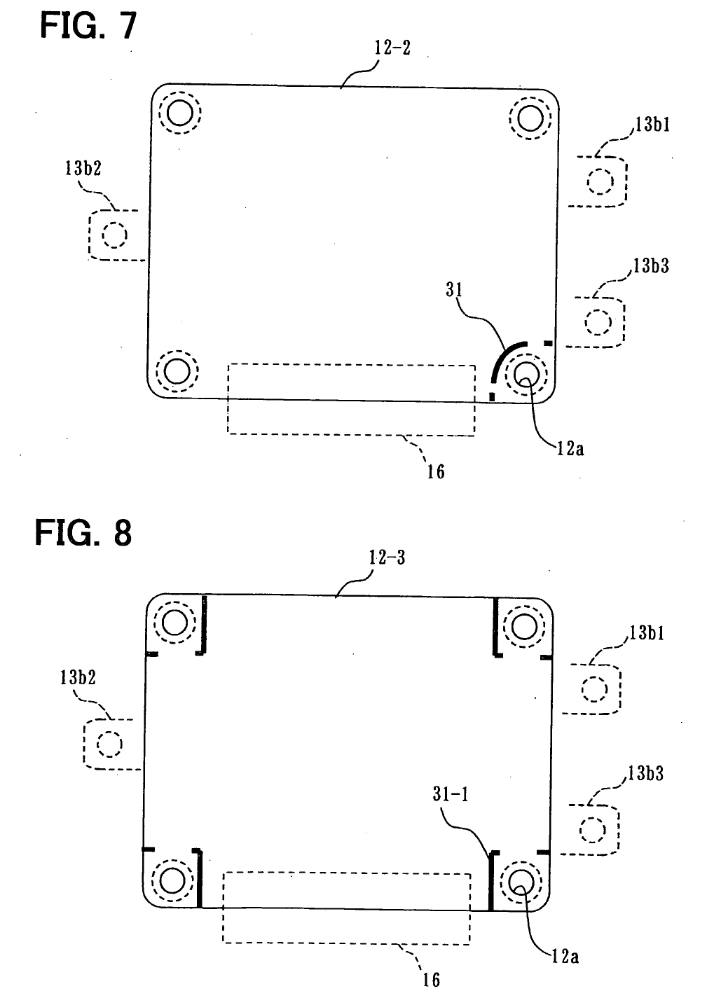

FIG. 7 illustrates a second modification of the first embodiment. As shown in FIG. 7, a dashed-shape slit 31 is defined at a single corner of a circuit board 12-2. The single corner is located the furthest from a front side of the vehicle. When the front-located mount parts 13b1, 13b2 are pushed upward in the arrow direction Y1 by the stress, the cover 13 is deformed in order of the front-and-right mount part 13b1, the middle-and-left mount part 13b2 and the rear-and-right mount part 13b3 in accordance with a distance from the front side of the vehicle.

Therefore, the rear-and-right mount part 13b3 operates as a fulcrum of a lever because the rear-and-right mount part 13b3 is located the furthest from the front side of the vehicle. The stress is most strongly applied to the rear-and-right mount part 13b3. The slit 31 is defined only around the screw hole 12a adjacent to the rear-and-right mount part 13b3.

The dashed-shape slit 31 defines a gap between the main area and the hole area. However, the main area and the hole area are partially connected with each other by a connecting part of the dashed-shape slit 31. When the connecting part of the slit 31 is damaged by the collision, the board 12-2 is separated from the cover 13 at the single slit 31. The stress is absorbed by the damaging and the separation, so that the ECU circuit 21 of the board 12-2 can be protected. The producing cost of the ECU 10 can be made much lower because the board 12-2 has the single slit 31 only.

FIG. 8 illustrates a third modification of the first embodiment. As shown in FIG. 8, the dashed-shape slits 31-1 are respectively defined at four corners of a circuit board 12-3, and respectively have angled shapes. The angled-shape slit 31-1 is a through groove passing through the board 12-3 in the thickness direction. The angled shape is constructed by a first linear line and a second linear line, that respectively and perpendicularly intersect the corresponding one of the first side and the second side of the corner portion. The angled-shape slit 31-1 is distanced from the screw hole 12a by a predetermined dimension. The board 12-3 is fixed to the cover 13 by the screw 15 because the main area is connected to the hole area by the connecting part of the angled-shape slit 31-1.

Similarly to FIG. 5, the connecting part of the slit 31-1 is damaged by the collision, so that the stress is absorbed by the damaging and the separation. Therefore, the electronic components mounted on the board 12-3 can be protected. Further, the producing cost of the ECU 10 can be made lower by just defining the angled-shape slits 31-1 in the board 12-3.

The angled-shape slit 31-1 may be defined at three corners of the board 12-3 similarly to FIG. 6, or at a single corner of the board 12-3 similarly to FIG. 7. In these cases, approximately the same advantages can be obtained.

In FIG. 8, the angled-shape slit 31-1 may be defined only one of the first linear line and the second linear line. In this case, the producing cost of the ECU 10 can be made much lower by just defining a single linear slit passing through the board 12-3 from the first side or the second side of the corner portion.

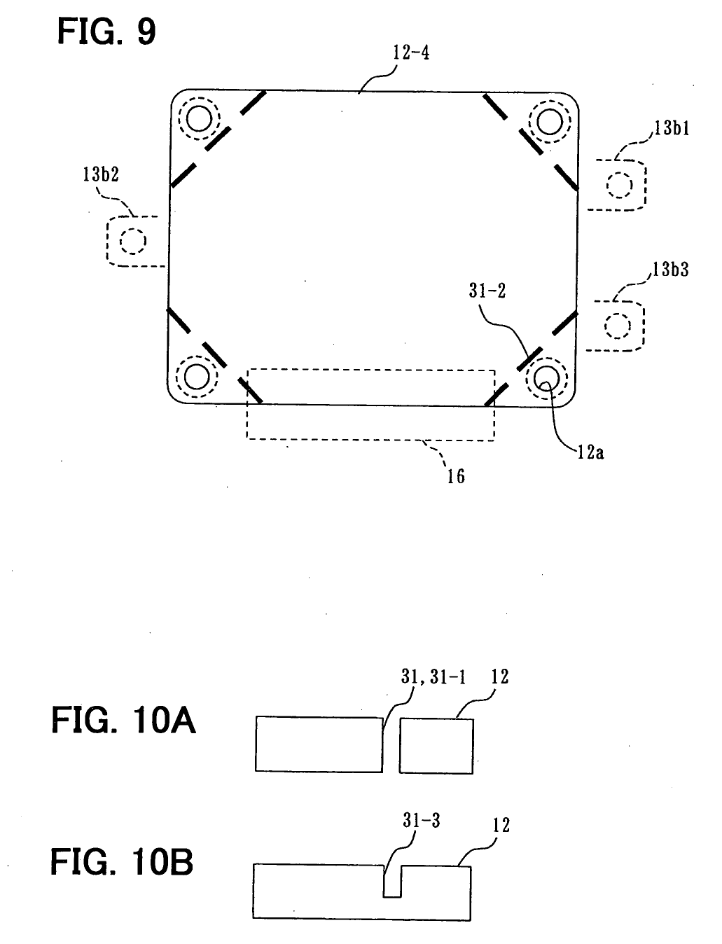

FIG. 9 illustrates a fourth modification of the first embodiment. As shown in FIG. 9, a dashed-shape slit 31-2 is defined at four corners of a circuit board 12-4, and has a linear shape. In this case, similarly to FIG. 5, the connecting part of the slit 31-2 is damaged by the collision, so that the stress is absorbed by the damaging and the separation. Therefore, the electronic components mounted on the board 12-4 can be protected. Further, the producing cost of the ECU 10 can be made lower by just defining the linear slits 31-2 in the board 12-4. The linear slit 31-2 may be defined at three corners of the board 12-4 similarly to FIG. 6, or at a single corner of the board 12-4 similarly to FIG. 7. In these cases, approximately the same advantages can be obtained.

FIG. 10A illustrates a cross-sectional view of the slit 31, 31-1 passing through the board 12 in the thickness direction. FIG. 10B illustrates a fifth modification of the first embodiment. As shown in FIG. 10B, the board 12 may have a based slit 31-3 in place of the through slit 31, 31-1. The based slit 31-3 corresponds to a concave groove. In this case, approximately the same advantages can be obtained as the above. The based slit 31-3 can be continuously defined from the first side to the second side without having the dashed shape. The board 12 having the based slit 31-3 is fixed to the cover 13 using the screw 15, and approximately the same advantages can be obtained. Further, the main area is not completely separated from the hole area by the based slit 31-3, so that the electronic components mounted to the main area of the circuit board 12 can be prevented from being affected by a resonance generated by vibration when the vehicle is running.

### Second Embodiment

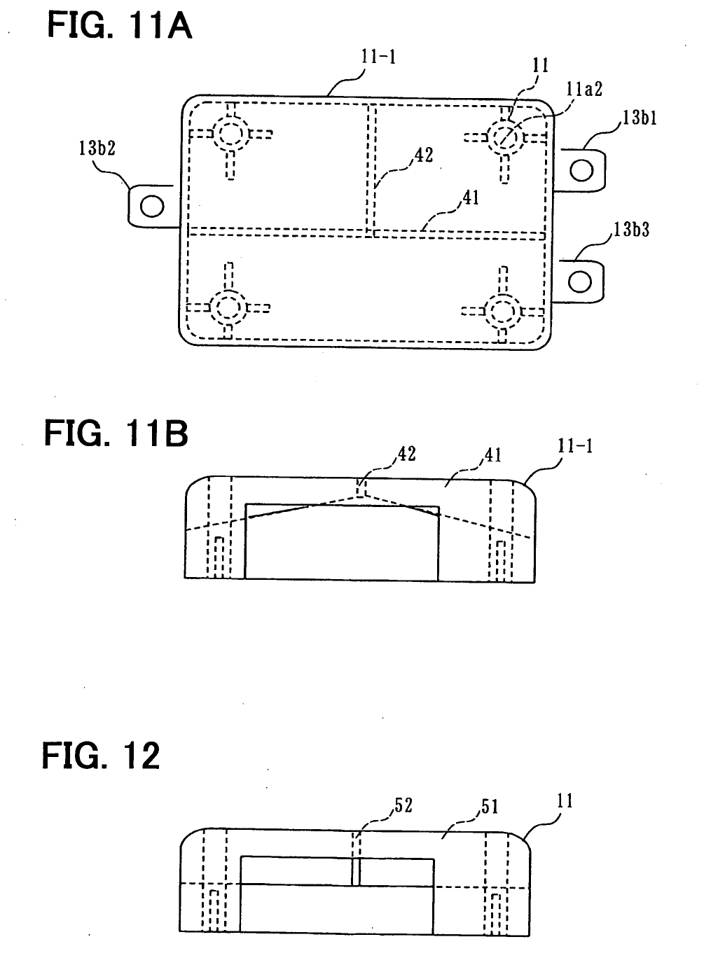

As shown in FIG. 11A, a casing 11-1 has a first beam 41 and a second beam 42. The beam 41, 42 strengthens the casing 11-1, and is made of resin material. The first beam 41 has a board shape approximately parallel with a front face of the casing 11-1, and is located at a center in a front-and-rear direction of the vehicle when the ECU 10 is fixed to the vehicle. The second beam 42 has a board shape approximately perpendicular to the first beam 41, and is fixed to the first beam 41. The second beam 42 is located at a middle of the first beam 41 in a left-and-right direction of the vehicle when the ECU 10 is fixed to the vehicle. The first beam 41 may be defined as a lateral beam, and the second beam 42 may be defined as a perpendicular beam.

As shown in FIG. 11B, an up-and-down dimension of the first beam 41 is narrowest at a position contacting with the second beam 42. The up-and-down dimension of the first beam 41 is gradually and linearly made larger as extending toward a side face of the casing 11-1. An up-and-down dimension of the second beam 42 is approximately the same as that of the first beam 41 at the narrowest position. Other construction of an ECU 10 of a second embodiment is approximately similar to that of the first embodiment.

FIG. 12 shows a comparison example with respect to FIG. 11B. A lateral beam 51 strengthens the casing 11, and has a uniform up-and-down dimension, compared with the first beam 41. A perpendicular beam 52 is made of a rectangular board having a uniform up-and-down dimension. In this case, a distortion of the casing 11 can be reduced when the vehicle has a collision because the casing 11 is strengthened by the beams 51, 52.

According to the second embodiment, the up-and-down dimension of the first beam 41 is narrowest at the center in the left-and-right direction, and the second beam 42 has the uniform up-and-down dimension equal to the narrowest dimension of the first beam 41. Therefore, if a front side of the ECU 10 is pushed upward when the vehicle has a collision, the casing 11 is distorted upward from both sides in the left-and-right direction, so that the casing 11 is deformed in a manner that the stress is most strongly applied to the rear-and-right mount part 13b3 of the cover 13 that is located the most rear side. Thus, the board 12 is damaged at the slit 31, 31-1, 31-2, 31-3.

The board 12 is easily damaged at the slit 31, 31-1, 31-2, 31-3 if the ECU 10 is constructed by the casing 11-1 of the second embodiment, compared with the comparison example. The stress applied when the vehicle has a collision can be absorbed by the damaging, so that the electronic components mounted on the board 12 can be protected.

The casing 11, 11-1 may be made of metal. The cover 13 may be made of resin.

The connector 16 is not limited to be located at the center in the left-and-right direction. The connector 16 may be located leftward or rightward from the center in the left-and-right direction.

The connector 16 and the board 12 overlaps with each other about a half length of the connector 16 in the front-and-rear direction. The connector 16 is directly soldered on a surface of the board 12, for example.

The slit 31-2 and the connector 16 are overlap with each other in FIG. 9. Alternatively, the slit 31-2 may be defined so as not to overlap with the connector 16 through a predetermined clearance.

Such changes and modifications are to be understood as being within the scope of the present invention as defined by the appended claims.

What is claimed is:

1. An electronic control unit for a vehicle comprising:
a box-shaped case having an opening face;
a cover closing the opening face of the case;
a board interposed between the case and the cover, the board having a plurality of corner portions constructed by a first side and a second side, the corner portions respectively having mount holes passing through the board, the first side and the second side being located on an outer periphery of the mount hole;
an electronic component mounted to the board; and
a fixing member passing through the mount hole so as to integrally fix the case, the cover and the board with each other, wherein
the board has a slit extending on an imaginary line defined to extend from the first side to the second side.

2. The electronic control unit according to claim 1, wherein
the slit has a dashed shape, and passes through the board in a thickness direction of the board.

3. The electronic control unit according to claim 1, wherein
the slit is a based groove defined in the board.

4. The electronic control unit according to claim 3, wherein
the based groove continuously extends from the first side to the second side on the imaginary line.

5. The electronic control unit according to claim 1, wherein
the slit has a curved shape.

6. The electronic control unit according to claim 1, wherein
the slit has an angled shape intersecting the corresponding one of the first side and the second side.

7. The electronic control unit according to claim 6, wherein
the angled shape of the slit is defined by two linear parts, and
the slit is defined only one of the two linear parts.

8. The electronic control unit according to claim 1, wherein
the slit has a linear shape.

9. The electronic control unit according to claim 1, wherein
the slit is defined in each of the plurality of corner portions of the board.

10. The electronic control unit according to claim 1, wherein
one of the plurality of corner portions disables to have the slit, and
the slit is defined in each of the other corner portions.

11. The electronic control unit according to claim 1, wherein
the slit is defined at a single corner portion of the plurality of corner portions, and
the single corner portion having the slit is located furthest from a front side of the vehicle, when the case, the cover and the board are integrally fixed to the vehicle.

12. The electronic control unit according to claim 1, wherein
the case, the cover and the board are integrally fixed to the vehicle,
the case includes
a first beam having a board shape extending approximately parallel with a front face of the case, the first beam being located at approximately center of the case in a front-and-rear direction of the vehicle, and
a second beam having a board shape extending approximately perpendicular to the first beam, the second beam being located at a middle of the case in a left-and-right direction of the vehicle,
an up-and-down dimension of the first beam is the smallest at a position intersecting the second beam, and gradually becomes larger toward a left/right face of the case, the first beam contacting the left-right face of the case, and
the second beam has a rectangular shape, and an up-and-down dimension of the second beam is uniform and approximately equal to the smallest up-and-down dimension of the first beam.

13. The electronic control unit according to claim 1, wherein
the case is made of resin material.

14. The electronic control unit according to claim 1, wherein
the mount hole has a female thread, and
the fixing member is a screw to be mounted to the female thread of the mount hole.

15. The electronic control unit according to claim 1, wherein
the slit is located at a position opposite from a vertex constructed by the first side and the second side through the mount hole, so that the mount hole is surrounded by the first side, the vertex, the second side and the slit.
